(19) United States
(12) Patent Application Publication
(10) Pub. No.: US 2004/0112541 A1
(43) Pub. Date: Jun. 17, 2004

(54) Plasma processor and plasma processing method

(76) Inventors: Nobuo Ishii, Amagasaki-shi (JP); Makoto Ando, Kawasaki-shi (JP); Masaharu Takahashi, Yachiyo-shi (JP); Yasuyoshi Yasaka, Uji-shi (JP)

Correspondence Address: FINNEGAN, HENDERSON, FARABOW, GARRETT & DUNNER, LLP, 1300 I STREET, NW, WASHINGTON, DC, 20005, US

(21) Appl. No.: 10/472,247

(22) PCT Filed: Mar. 19, 2002
(86) PCT No.: PCT/JP02/02627

(30) Foreign Application Priority Data
Mar. 22, 2001 (JP) 2001-82769

(51) Int. Cl. H01L 21/306

(52) U.S. Cl. 156/345.41

(57) ABSTRACT

A radial antenna (30) for supplying an electromagnetic field into a processing vessel has slots (36) that are arranged along a spiral line having an interval d of approximately N times (N is a natural number) a wavelength λg of the electromagnetic field within the radial antenna (30). The electromagnetic field is fed from the center of the radial antenna (30) in a rotational mode.

### TECHNICAL FIELD

The present invention relates to a plasma processing apparatus and a plasma processing method in which an electromagnetic field is supplied from a radial antenna to a processing vessel and plasma generated in the processing vessel is used for processing a subject to be processed.

### BACKGROUND ART

In manufacture of semiconductor devices, flat panel displays and the like, plasma processing apparatuses are commonly used for formation of an oxide film, crystal growth of a semiconductor layer, etching, ashing and other processing. One of such plasma processing apparatuses is a radio frequency plasma processing apparatus where a radio frequency electromagnetic field is supplied from an antenna to a processing vessel to generate plasma by ionizing a gas within the processing vessel by action of the electromagnetic field. The radio frequency plasma processing apparatus is capable of generating high-density plasma under a low pressure, thereby ensuring efficient plasma processing.

In the radio frequency plasma processing apparatus, it is necessary to introduce the electromagnetic field efficiently into the plasma so as to improve the plasma generation efficiency. To this end, a method of feeding a circularly polarized wave to a radial antenna has been proposed, which is now described.

FIG. 6 is a cross sectional view showing a configuration of a conventional radio frequency plasma processing apparatus of a type feeding a circularly polarized wave to a radial antenna.

This plasma processing apparatus has a processing vessel 111 of a cylindrical shape closed at the bottom and open at the top. A substrate stage 122 is secured at the bottom of processing vessel 111, and a substrate 121 to be processed is placed on the upper surface of substrate stage 122. A nozzle 117 for supplying a plasma gas is provided at the sidewall of processing vessel 111. An exhaust port 116 for evacuation is provided at the bottom of processing vessel 111. A dielectric plate 113 closes the open top of processing vessel 111 to prevent leakage of the plasma therefrom to the outside.

A radial antenna 130 is placed on top of dielectric plate 113. Radial antenna 130 is formed of two circular conductor plates 131 and 132 parallel to each other and forming a radial waveguide 133, and a conductor ring 134 connecting peripheral portions of conductor plates 131 and 132. Here, a diameter of radial antenna 130 is made four times a guide wavelength λkg of an electromagnetic field inside radial antenna 130, i.e., inside radial waveguide 133.

A plurality of slots 136 are formed at conductor plate 131 to be a radiating surface of radial waveguide 133. Slots 136 are arranged along concentric circles in a peripheral direction perpendicular to a radial direction of conductor plate 131, as shown in FIG. 7.

An introduction port 135 for an electromagnetic field F is formed at the center of conductor plate 132 as a back surface of radial waveguide 133. A radio frequency generator 144 is connected to introduction port 135 via a cylindrical waveguide 141. Further, a circular polarization converter 142 is provided to cylindrical waveguide 141 for feeding a circularly polarized TE₁₁ wave to radial antenna 130.

An annular shield member 112 covers peripheries of dielectric plate 113 and radial antenna 130 to prevent leakage of electromagnetic field F to the outside.

FIG. 8A is a conceptual diagram showing an electric field inside radial antenna 130, i.e., inside radial waveguide 133, specifically showing a wavefront of the electric field at a given time point. FIG. 8B is a diagram showing the electric field inside radial antenna 130, i.e., inside radial waveguide 133, specifically showing a waveform of the electric field in a radial direction of radial waveguide 133. FIG. 8C is a diagram showing the electric field inside radial antenna 130, i.e., inside radial waveguide 133, specifically showing a waveform of the electric field in a peripheral direction of radial waveguide 133.

In the interior of radial antenna 130 fed with the circularly polarized TE₁₁ wave, a travelling wave of electromagnetic field F propagating from the center to the periphery of radial waveguide 133 and a reflected wave reflected by conductor ring 134 and returning to the center are superposed, resulting in a standing wave having fixed amplitude distribution of electric field E in a radial direction of radial waveguide 133. The electric field waveform in a radial direction of the standing wave becomes a sinusoidal waveform with four waves, as shown in FIG. 8B. The electric field waveform in a peripheral direction of the standing wave becomes a sinusoidal waveform with one wave, as shown in FIG. 8C. Points A-D in FIG. 8C correspond to points A-D in FIG. 8A, respectively.

The electric field having the fixed amplitude distribution in a radial direction becomes a travelling wave in a peripheral direction of radial waveguide 133, which rotates at a frequency the same as the frequency of electromagnetic field F supplied to radial waveguide 133.

The travelling wave rotating in a peripheral direction through a region of a radius R of radial waveguide 133 has a wavelength of 2πR. Thus, in a region where an actual guide wavelength is λg<2πR, the guide wavelength appears to be longer in a peripheral direction of radial waveguide 133. When a supply frequency is high at 2.45 GHz, for example, λg<2πR stands in almost all the regions except the center of radial waveguide 133.

When a relative dielectric constant in radial antenna 130 is represented as ε₁ and a wavelength of the electromagnetic field in vacuum is represented as λ0.

λg=λ₀/ε₁^{1/2}, and thus, relative dielectric constant ε₁ in radial antenna 130 becomes small in appearance.

FIG. 9 is a conceptual diagram showing an enlarged view of an interface between the radiating surface of radial antenna 130 and plasma P within processing vessel 111.

When a relative dielectric constant of a region 150 between the radiating surface of antenna 130 including dielectric plate 113 shown in FIG. 6 and a surface of plasma P is represented as ε₂ and a relative dielectric constant within plasma P is represented as ε₃, it is known that an incident angle θ of electromagnetic field F with respect to a normal direction of the surface of plasma P is expressed as:

θ=sin⁻¹(ε₁/ε₃)^{1/2} (1)

independent of relative dielectric constant ε₂ of region 150. In order for the expression (1) to have a solution and in order for the electromagnetic field F to enter into plasma P,

ε₁<ε₃ (2)

should be satisfied.

As described above, in the plasma processing apparatus shown in FIG. 6, relative dielectric constant ε₁ in radial antenna 130 can be made small in appearance by feeding the circularly polarized TE₁₁ wave to radial antenna 130. Thus, by satisfying the expression (2), it is possible to reduce the reflected amount of electromagnetic field F to realize efficient introduction of electromagnetic field F into plasma P.

FIG. 10 shows a change in incident angle θ of electromagnetic field F in a radial direction in the plasma processing apparatus shown in FIG. 6. Here, a supply frequency is 2.45 GHz, and a mean value of relative dielectric constant ε₃ within plasma P is 0.5. The horizontal axis represents a distance r [cm] in a radial direction from a central axis of processing vessel 111, and the vertical axis represents an incident angle θ [°] of electromagnetic field F to plasma P. Incident angle θ of electromagnetic field F is about 34° at a position where r=5 cm. It decreases inversely proportional to an increase of r, and becomes lower than 10° in a region where r is more than 16 cm.

It is generally known, in a radio frequency plasma processing apparatus, that absorption efficiency of electromagnetic field F increases as incident angle θ of electromagnetic field F to plasma P increases, allowing efficient generation of plasma. As such, the conventional plasma processing apparatus shown in FIG. 6 suffers a problem that plasma cannot be generated efficiently in a region far away from the central axis of processing vessel 111 where incident angle θ of electromagnetic field F is small.

Further, when processing vessel 111 and radial antenna 130 are increased in diameter to meet the demand for an increase in diameter of substrate 121 to be processed, the distance from the central axis of processing vessel 111 to the sidewall increases correspondingly. Incident angle θ of electromagnetic field F further decreases in a region near the sidewall, causing more considerable degradation of the plasma generation efficiency.

The present invention has been made to solve the above-described problems, and its object is to improve efficiency of plasma generation.

### DISCLOSURE OF THE INVENTION

To achieve the above object, a plasma processing apparatus according to the present invention includes a stage accommodated in a processing vessel and on which a subject to be processed is mounted, and a radial antenna having a radiating surface provided with a plurality of slots and supplying an electromagnetic field into the processing vessel. The slots of the radial antenna are arranged along a spiral line having an interval of approximately N times (N is a natural number) a wavelength of the electromagnetic field in the radial antenna.

When the slots are arranged along a spiral line, compared to the case where they are arranged along concentric circles, a phase change in each slot per period of the electromagnetic field becomes large. A relative dielectric constant within the radial antenna also increases in appearance proportional to the phase change. Thus, it is possible to increase the incident angle of the electromagnetic field with respect to a normal direction of the plasma surface. Further, since the interval of the spiral line along which the slots are arranged is made approximately N times the wavelength of the electromagnetic field within the radial antenna, the incident angles of the electromagnetic field match in a radial direction of the radial antenna. This ensures efficient supply of the electromagnetic field from the radial antenna to the processing vessel. In the case where the interval between the radiating surface of the radial antenna and the plasma surface is not greater than a half of the wavelength of the electromagnetic field in a region between the radiating surface and the plasma surface, it is unnecessary to make the interval of the spiral line approximately N times the wavelength of the electromagnetic field within the radial antenna.

In the case where the electromagnetic field is not fed in a rotational mode, it is preferable to satisfy N≧3. By doing so, it is possible to ensure a sufficiently large incident angle of the electromagnetic field in a region near the sidewall of the processing vessel even if the processing vessel and the radial antenna are increased in diameter.

The plasma processing apparatus described above may further include feeding means connected to a central portion of the radial antenna for feeding the electromagnetic field in the rotational mode. This causes the phase change in each slot per period of the electromagnetic field to increase by 2π (radian). Consequently, the relative dielectric constant in the radial antenna further increases in appearance. Thus, it is possible to further increase the incident angle of the electromagnetic field.

When the electromagnetic field is fed in the rotational mode, it is preferable to satisfy N≧2. This ensures the same conditions as in the case where N≧3 is satisfied when the electromagnetic field is not fed in the rotational mode.

A plasma processing method according to the present invention includes the step of preparing a radial antenna having a radiating surface provided with a plurality of slots which are arranged along a spiral line having an interval of approximately N times (N is a natural number) a wavelength of an electromagnetic field within the radial antenna, and the step of processing a subject to be processed by arranging the subject in a processing vessel, supplying the electromagnetic field via the slots arranged at the radiating surface of the radial antenna into the processing vessel, and by using plasma generated within the processing vessel for the processing of the subject to be processed.

When the slots are arranged along a spiral line, the phase change in each slot per period of the electromagnetic filed increases compared to the case where the slots are arranged concentrically. A relative dielectric constant within the radial antenna also increases in appearance proportional to the phase change. Thus, it is possible to increase the incident angle of the electromagnetic field with respect to a normal direction of the plasma surface. The interval of the spiral line along which the slots are arranged is set approximately N times the wavelength of the electromagnetic field within the radial antenna. Thus, the incident angles of the electromagnetic field match in a radial direction of the radial antenna. Accordingly, it is possible to efficiently supply the electromagnetic field from the radial antenna into the processing vessel. In the case where the interval between the radiating surface of the radial antenna and the plasma surface is not greater than a half of the wavelength of the electromagnetic field in a region between the radiating surface and the plasma surface, it is unnecessary to make the interval of the spiral line approximately N times the wavelength of the electromagnetic field within the radial antenna.

Here, it is preferable to satisfy N≧3 when the electromagnetic field is not fed in a rotational mode.

The electromagnetic field may be fed from the central portion of the radial antenna in the rotational mode. When the electromagnetic field is fed in the rotational mode, it is preferable to satisfy N≧2.

### BRIEF DESCRIPTION OF THE DRAWINGS

FIG. 1 is a cross sectional view showing a configuration of an etching apparatus as an embodiment of the present invention.

FIG. 2 is a plan view of a radiating surface of a radial antenna when seen from the II-II line direction shown in FIG. 1.

FIG. 3A is a conceptual diagram showing an electric field within a radial antenna 30, i.e., within a radial waveguide 33, specifically showing a wavefront of the electric field at a given time point.

FIG. 3B is a diagram showing the electric field within radial antenna 30, i.e., within radial waveguide 33, specifically showing a waveform of the electric field in a radial direction of radial waveguide 33.

FIG. 3C is a diagram showing the electric field within radial antenna 30, i.e., within radial waveguide 33, specifically showing a waveform of the electric field in a peripheral direction of radial waveguide 33.

FIG. 4 shows a change in incident angle of the electromagnetic field in a radial direction.

FIG. 5 is a plan view showing another configuration of the radiating surface of the radial antenna.

FIG. 6 is a cross sectional view showing a configuration of a conventional radio frequency plasma processing apparatus of a type feeding a circularly polarized wave to a radial antenna.

FIG. 7 is a plan view showing a configuration of a radiating surface of the radial antenna.

FIG. 8A is a conceptual diagram showing an electric field within a radial antenna 130, i.e., within a radial waveguide 133, specifically showing a wavefront of the electric field at a given time point.

FIG. 8B is a diagram showing the electric field within radial antenna 130, i.e., within radial waveguide 133, specifically showing a waveform of the electric field in a radial direction of radial waveguide 133.

FIG. 8C is a diagram showing the electric field within radial antenna 130, i.e., within radial waveguide 133, specifically showing a waveform of the electric field in a peripheral direction of radial waveguide 133.

FIG. 9 is a conceptual diagram showing an enlarged view of an interface between the radiating surface of the radial antenna and plasma within the processing vessel.

FIG. 10 shows a change in incident angle of the electromagnetic field in a radial direction.

### BEST MODES FOR CARRYING OUT THE INVENTION

Hereinafter, an embodiment of the present invention will be described in detail with reference to the drawings. Here, the case of applying the present invention to an etching apparatus is explained by way of example. FIG. 1 is a cross sectional view showing a configuration of an etching apparatus as an embodiment of the present invention.

This plasma processing apparatus has a processing vessel 11 of a cylindrical shape closed at the bottom and open at the top. A substrate stage 22 is secured at the bottom of processing vessel 11, and a substrate 21 to be processed is placed on the upper surface of substrate stage 22. A nozzle 17 is provided on the sidewall of processing vessel 11, through which a plasma gas such as Ar or an etching gas such as CF₄ is introduced into processing vessel 11. An exhaust port 16 for evacuation is provided at the bottom of processing vessel 11. The open top of processing vessel 11 is closed with a dielectric plate 13 to prevent leakage of the plasma therefrom to the outside.

A radial antenna 30 is placed on top of dielectric plate 13. Radial antenna 30 is isolated from processing vessel 11 by dielectric plate 13, and protected from plasma P that is generated within processing vessel 11. Peripheries of dielectric plate 13 and radial antenna 30 are covered with a shield member 12 that is arranged annularly on the sidewall of processing vessel 11, preventing leakage of electromagnetic field F to the outside.

The central portion of radial antenna 30 is connected to a radio frequency generator 44 via a cylindrical waveguide 41. Radio frequency generator 44 generates a radio frequency electromagnetic field F of a prescribed frequency in a range from one GHz to ten-odd GHz. A matching circuit 43 for impedance matching and a circular polarization converter 42 for rotating a primary direction of the electric field propagating through cylindrical waveguide 41 about a tube axis are provided in midstream of cylindrical waveguide 41. Matching circuit 43 may be provided between radio frequency generator 44 and circular polarization converter 42, or between circular polarization converter 42 and radial antenna 30. The above-described cylindrical waveguide 41, circular polarization converter 42, matching circuit 43, and radio frequency generator 44 constitute means for feeding a circularly polarized TE₁₁ wave to radial antenna 30.

A configuration of radial antenna 30 is now described in detail.

Radial antenna 30 is formed of two circular conductor plates 31 and 32 parallel to each other and forming a radial waveguide 33, and a conductor ring 34 connecting peripheral portions of conductor plates 31 and 32 for shielding. Conductor plates 31, 32 and conductor ring 34 are formed of a conductor such as copper or aluminum.

An introduction port 35 for introducing electromagnetic field F into radial waveguide 33 is formed at the center of conductor plate 32 as an upper surface of radial waveguide 33. Cylindrical waveguide 41 described above is connected to introduction port 35.

In the interior of radial waveguide 33, a conular member 37 is provided at the center of conductor plate 31, protruding toward introduction port 35. Conular member 37 is formed of the same conductor as conductor plates 31, 32 and others. Conular member 37 effectively guides electromagnetic field F having propagated through cylindrical waveguide 41 into radial waveguide 33.

Conductor plate 31 as a lower surface of radial waveguide 33 is provided with a plurality of slots 36 for supplying electromagnetic field F propagating in radial waveguide 33 to processing vessel 11. Conductor plate 31 constitutes a radiating surface of radial antenna 30.

Here, a diameter of radial antenna 30 is made eight times a guide wavelength λg of the electromagnetic field inside radial antenna 30, i.e., inside radial waveguide 33.

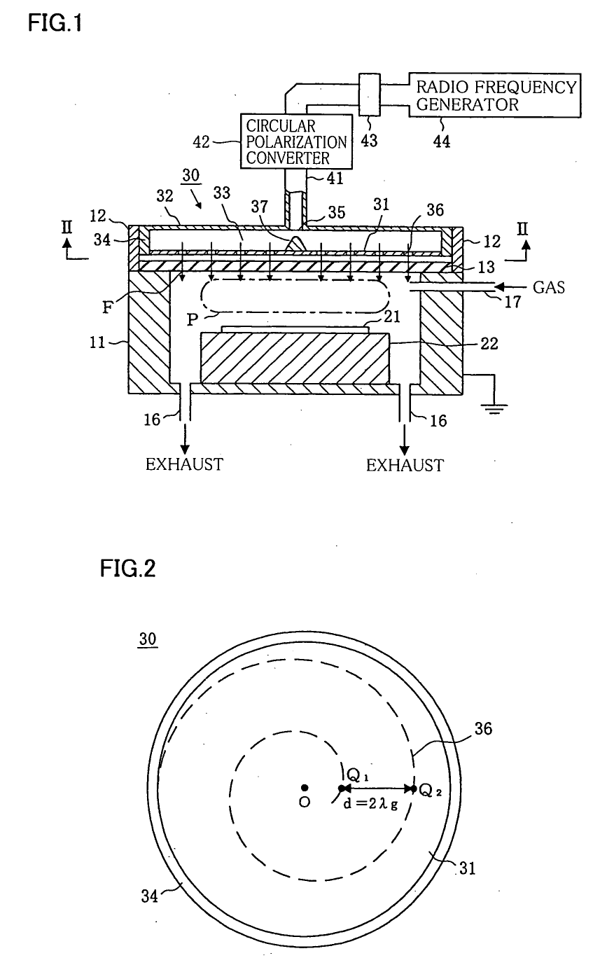

FIG. 2 is a plan view of radial antenna 30 when seen from the II-II line direction shown in FIG. 1.

Slots 36 formed at the radiating surface of radial antenna 30 are arranged along a spiral (or helical) line extending from the center O to the periphery of the radiating surface. When the electromagnetic field is supplied in a rotational mode, the rotation direction of the spiral line is made equal to the rotation direction of the electromagnetic field in radial antenna 30. Slots 36 may be curved or straight.

The spiral line shown in FIG. 2 is a so-called Archimedean, which is expressed with polar coordinates (r, θ) as:

r=aθ (3)

where a is a constant. Here, a=λg/π, λg being a guide wavelength of the electromagnetic field in radial antenna 30. When a point Q₂ on the spiral line is reached after a rotation (2π) from a point Q₁ on the spiral line, and when an interval between points Q₁ and Q₂ is defined as an interval d of the spiral line, this spiral line has interval d of 2λg.

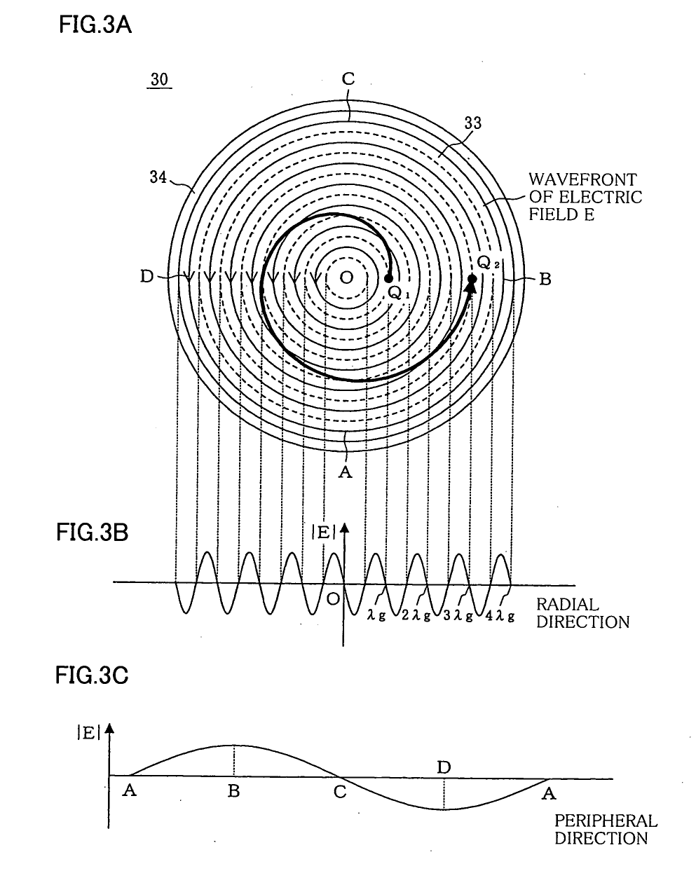

FIG. 3A is a conceptual diagram showing the electric field within radial antenna 30, i.e., within radial waveguide 33, specifically showing a wavefront of the electric field at a given time point. FIG. 3B is a diagram showing the electric field within radial antenna 30, i.e., within radial waveguide 33, specifically showing a waveform of the electric field in a radial direction of radial waveguide 33. FIG. 3C is a diagram showing the electric field within radial antenna 30, i.e., within radial waveguide 33, specifically showing a waveform of the electric field in a peripheral direction of radial waveguide 33.

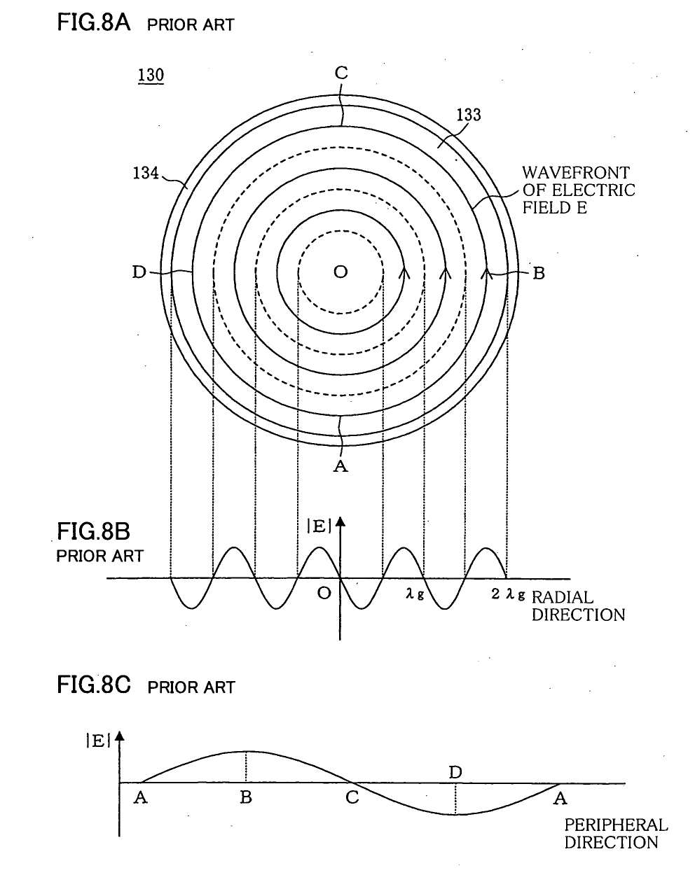

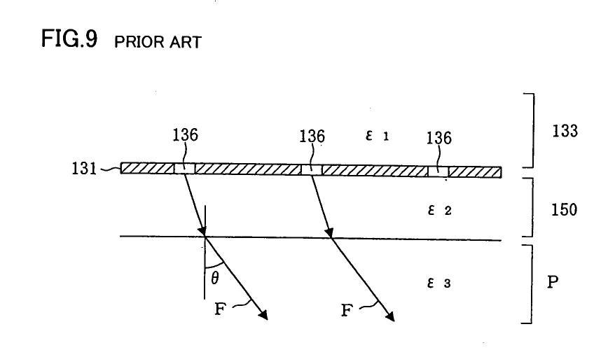

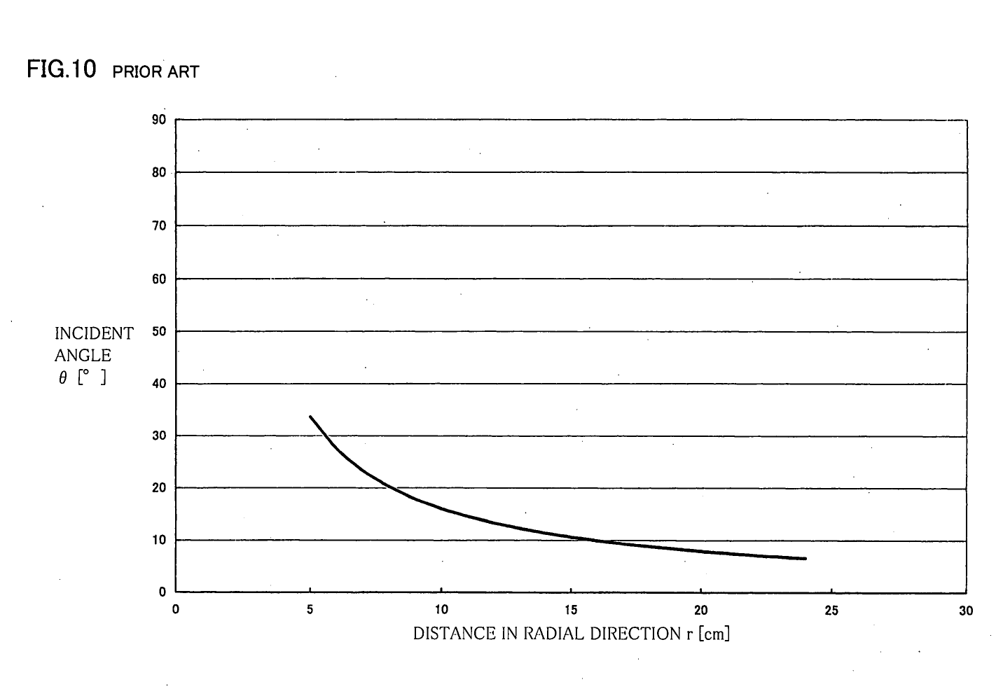

When a circularly polarized TE₁₁ wave is fed to radial antenna 30, the electric field within radial antenna 30 becomes a standing wave of a wavelength λg in a radial direction, and becomes a travelling wave in a peripheral direction which rotates at a frequency the same as the supply frequency, as in the case of FIGS. 8A-8C.

Thus, the phase change of the electromagnetic field through a rotation from point Q₁ to point Q₂ on the spiral line having interval d=2λg becomes 6 π (radian) as a sum of the phase change of 2 π (radian) in the peripheral direction and the phase change of 2×2 π (radian) in the radial direction. Accordingly, when slots 36 are arranged along the spiral line having interval d=2 λg, the phase change at each slot 36 per period corresponding to one rotation of the travelling wave becomes 6 π (radian).

When slots 136 are arranged concentrically as in the conventional case, the phase change of the electromagnetic field at each slot 136 per period is only the phase change of 2 π (radian) in the peripheral direction. As such, the phase change triples by arranging slots 36 along the spiral line having interval d=2 λg. The number of waves k also triples, proportional to the phase change of the electromagnetic field per period. As the number of waves k triples, relative dielectric constant ε₁ in antenna 30 becomes nine times in appearance, since the number of waves k is proportional to the square root of relative dielectric constant ε₁.

When a relative dielectric constant within plasma P generated in processing vessel 11 is represented as ε₃, incident angle θ of electromagnetic field F with respect to a normal direction of the surface of plasma P is expressed by the expression (1) above. Thus, it is possible to increase incident angle θ of electromagnetic field F to plasma P by arranging slots 36 along a spiral line as described above and thereby increasing relative dielectric constant ε₁ in antenna 30 in appearance. This improves the absorption efficiency of electromagnetic field F by plasma P, and accordingly, plasma can be generated more efficiently than in the conventional case.

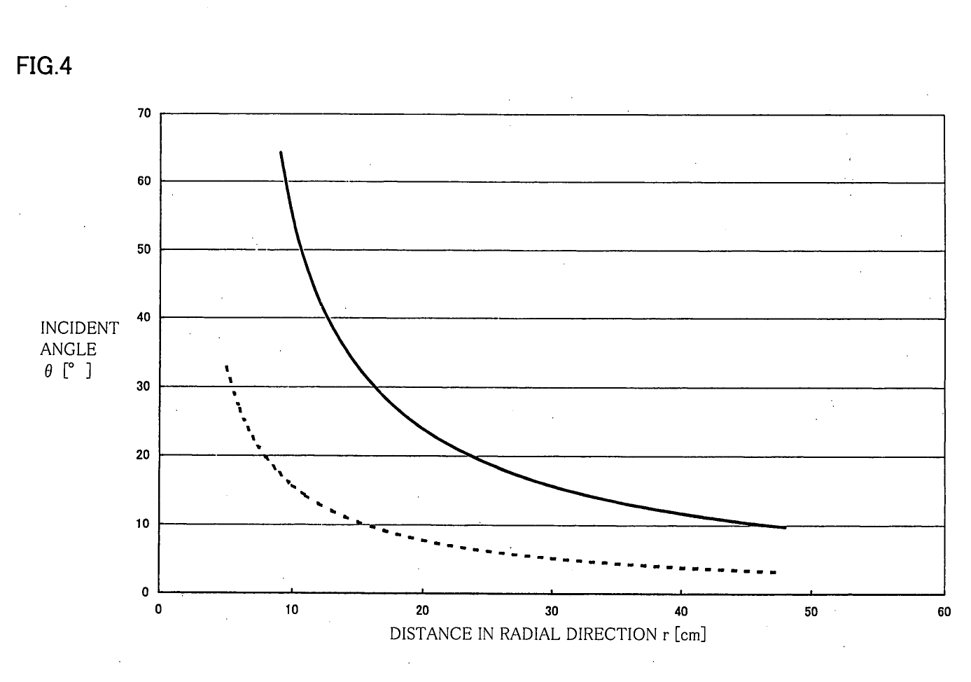

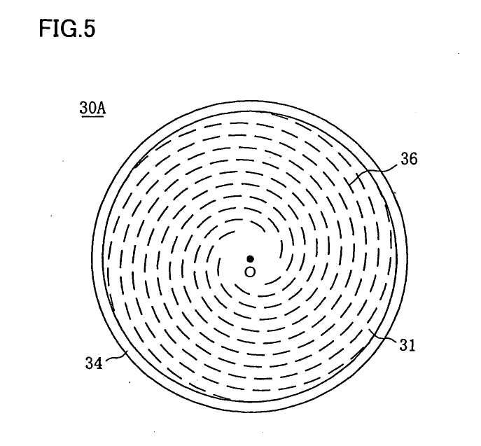

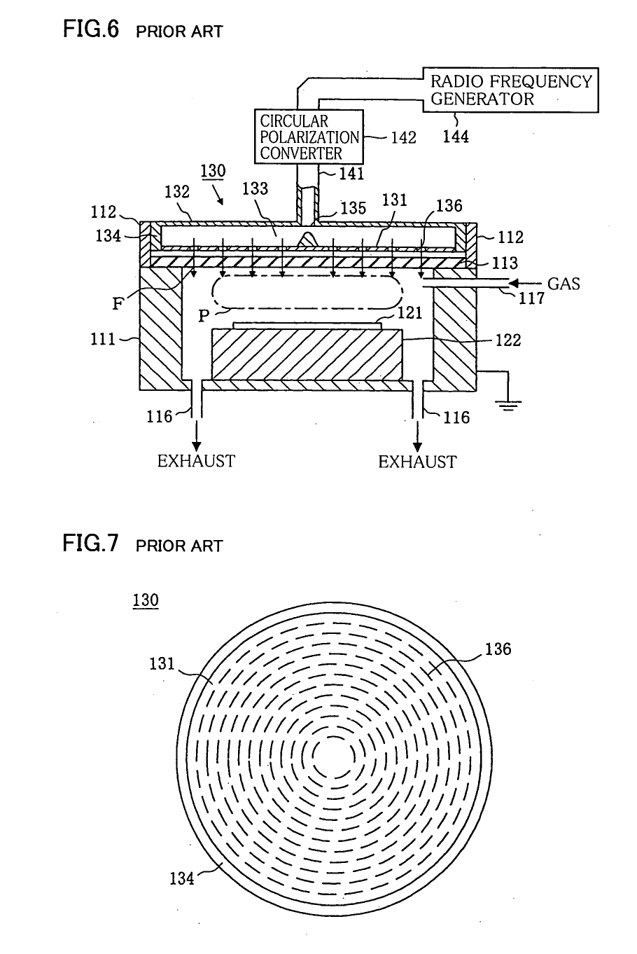

FIG. 4 shows a change of incident angle θ of electromagnetic field F in a radial direction. Supply frequency is 2.45 GHz, and a mean value of relative dielectric constant ε₃ in plasma P is 0.5. The horizontal axis represents a distance r [cm] from the central axis of the processing vessel in a radial direction, and the vertical axis represents an incident angle θ [°] of electromagnetic field F to plasma P. A broken line represents incident angle θ when a circularly polarized wave is fed to radial antenna 130 shown in FIGS. 6 and 7. A solid line represents incident angle θ when a circularly polarized wave is fed to radial antenna 30 shown in FIGS. 1 and 2.

It is found from FIG. 4 that arranging slots 36 along the spiral line having interval d=2 λg ensures sufficiently large incident angle θ of 15.7° even in a region where r is 30 cm. As such, even if diameters of processing vessel 11 and radial antenna 30 are made large to meet the demand for an increase in diameter of substrate 21 to be processed, it is possible to prevent degradation of the plasma generation efficiency in a region near the sidewall of processing vessel 11.

Although the case of arranging slots 36 along a single spiral line as in radial antenna 30 of FIG. 2 has been described above, slots 36 may be arranged along a plurality of spiral lines provided at equal intervals about a center O of a radiating surface as in a radial antenna 30A shown in FIG. 5. In this case, each spiral line has an equal interval d of d=2 λg. Arranging slots 36 along a plurality of spiral lines in this manner increases the density of slots 36 over the radiating surface, thereby improving radiation efficiency.

When slots 36 are arranged along a plurality of spiral lines, however, the slot density may be increased in an inner region (close to the center O) of the radiating surface than in an outer region (close to the periphery). Thus, in the case where the slot density in the inner region becomes too high, a spiral line provided with slots 36 in the inner region and a spiral line unprovided with slots 36 in the inner region may be arranged alternately. Alternatively, the slots in the inner region of the radiating surface may be made relatively short, and the slots in the outer region may be made relatively long.

Interval d of the spiral line(s) along which slots 36 are arranged only needs to be approximately a natural number N of times the guide wavelength λg. This makes incident angles θ of electromagnetic field F to plasma P match in the radial direction of radial antenna 30, 30A, ensuring efficient supply of electromagnetic field F from radial antenna 30, 30A to processing vessel 11. Interval d of the spiral line does not have to be exactly N×λg, but may be approximately (N±0.1)×λg. In the case where a circularly polarized wave is fed to a radial antenna having slots 36 arranged along a spiral line of interval d=N×λg, the phase change in each slot 36 per period becomes (N+1)×2π (radian).

Relative dielectric constant ε₁ in appearance within radial antenna 30, 30A increases as an increase of N. Thus, when a circularly polarized wave is fed to radial antenna 30, 30A, if N≧2, it is possible to prevent degradation of plasma generation efficiency in a region near the sidewall of processing vessel 11, even if diameters of processing vessel 11 and radial antenna 30 are made large.

Although the feeding means formed of cylindrical waveguide 41, circular polarization converter 42, matching circuit 43 and radio frequency generator 44 has been used to feed a circularly polarized TE₁₁ wave to radial antenna 30 in the etching apparatus shown in FIG. 1, a similar effect can be obtained when the electromagnetic field is fed to radial antenna 30, 30A in the rotational mode. As another way of feeding the electromagnetic field in the rotational mode, perturbation may be applied to the electromagnetic field of the TM11 mode in a cavity to rotate the same, and the rotated electromagnetic field may be fed to radial antenna 30, 30A.

Feeding to radial antenna 30, 30A, however, does not necessarily have to be in the rotational mode. In the case where radial antenna 30, 30A having slots 36 arranged along a spiral line of interval d=N×λg is fed coaxially, for example, the phase change in each slot 36 per period becomes only the phase change of N×2π (radian) in a radial direction, without the phase change of 2 π (radian) in a peripheral direction. Thus, a similar effect can be obtained, even if not feeding in the rotational mode, when interval d of the spiral line along which slots 36 are arranged is increased by λg than in the case of feeding in the rotational mode. As such, in the case where radial antenna 30, 30A is not fed in the rotational mode, degradation in plasma generation efficiency in a region near the sidewall of processing vessel 11 can be prevented by setting N≧3, even if processing vessel 11 and radial antenna 30 are increased in diameter.

In radial antennas 30, 30A shown in FIGS. 2 and 5, every slot 36 is arranged to have its longitudinal direction along the spiral line. Alternatively, a plurality of pairs of non-parallel slots, each pair of slots having their extensions crossing each other at right angles, may be arranged along a spiral line having interval d=N×λg.

The plasma processing apparatus of the present invention may also be applied to an ECR (electron cyclotron resonance) plasma processing apparatus. Further, it can be utilized, not only for the etching apparatus, but also for a plasma CVD apparatus and the like.

As described above, according to the present invention, slots of a radial antenna for supplying an electromagnetic field into a processing vessel are arranged along a spiral line having an interval of approximately N times (N is a natural number) the wavelength of the electromagnetic field in the radial antenna. When the slots are arranged along the spiral line, the phase change in each slot per period of the electromagnetic field increases compared to the case of arranging the slots concentrically. A relative dielectric constant in the radial antenna increases in appearance proportional to the phase change. Accordingly, it is possible to increase the incident angle of the electromagnetic field with respect to a normal direction of the plasma surface, to improve efficiency of plasma generation. Further, since the interval of the spiral line along which the slots are arranged is made approximately N times (N is a natural number) the wavelength of the electromagnetic field in the radial antenna, the incident angles of the electromagnetic field match in a radial direction of the radial antenna. Accordingly, the electromagnetic field can be supplied from the radial antenna to the processing vessel efficiently, and thus, the plasma generation efficiency increases.

Further, feeding the electromagnetic field from the center of the radial antenna in the rotational mode makes the phase change in each slot per period of the electromagnetic field increase by 2 π (radian). As such, the relative dielectric constant in the radial antenna further increases in appearance, and accordingly, the plasma generation efficiency can further be improved.

N≧3 is satisfied when the electromagnetic field is not fed in the rotational mode, while N≧2 is satisfied when the electromagnetic field is fed in the rotational mode. This ensures sufficient plasma generation efficiency in a region near the sidewall of the processing vessel even in the case where diameters of the processing vessel and the radial antenna are made large.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

Industrial Applicability

The present invention is applicable to an ECR (electron cyclotron resonance) plasma processing apparatus. Further, it can be utilized, not only for an etching apparatus, but also for a plasma CVD apparatus and others.

1. A plasma processing apparatus, comprising:
a stage (22) accommodated in a processing vessel (11) and having a subject to be processed (21) mounted thereon; and
a radial antenna (30, 30A) having a radiating surface (31) provided with a plurality of slots (36) and supplying an electromagnetic field into said processing vessel (11),
said slots (36) of said radial antenna (30, 30A) being arranged along a spiral line having an interval of approximately N times (N is a natural number) a wavelength of the electromagnetic field within said radial antenna (30, 30A).

2. The plasma processing apparatus according to claim 1, wherein N is at least 3.

3. The plasma processing apparatus according to claim 1, further comprising feeding means (43, 44) connected to a central portion of said radial antenna (30, 30A) for feeding the electromagnetic field in a rotational mode.

4. The plasma processing apparatus according to claim 3, wherein N is at least 2.

5. A plasma processing method, comprising the steps of:
preparing a radial antenna (30, 30A) having a radiating surface (31) provided with a plurality of slots (36), said slots (36) being arranged along a spiral line having an interval of approximately N times (N is a natural number) a wavelength of an electromagnetic field within said radial antenna (30, 30A); and
processing a subject to be processed (21) by arranging said subject (21) in a processing vessel (11), by supplying the electromagnetic field via said slots (36) arranged at the radiating surface (31) of said radial antenna (30, 30A) into said processing vessel (11), and by using plasma generated within said processing vessel (11) to process said subject.

6. The plasma processing method according to claim 5, wherein N is at least 3.

7. The plasma processing method according to claim 5, wherein said step of processing a subject to be processed (21) includes the step of feeding the electromagnetic field from a central portion of said radial antenna (30, 30A) in a rotational mode.

8. The plasma processing method according to claim 7, wherein N is at least 2.
